(19) United States
(12) Patent Application Publication
(10) Pub. No.: US 2026/0202734 A1
(43) Pub. Date: Jul. 16, 2026

(54) PHASE-SHIFTING PHOTOMASK

(71) Applicant: Powerchip Semiconductor Manufacturing Corporation, Hsinchu (TW)

(72) Inventor: Yi-Kai Lai, Taoyuan City (TW)

(73) Assignee: Powerchip Semiconductor Manufacturing Corporation, Hsinchu (TW)

(21) Appl. No.: 19/061,864

(22) Filed: Feb. 24, 2025

(30) Foreign Application Priority Data
Jan. 13, 2025 (TW) 114101268

(51) Int. Cl. G03F 1/26; G03F 7/00

(52) U.S. Cl. CPC G03F 1/26; G03F 7/70091

(57) ABSTRACT

The present disclosure provides a phase-shifting photomask including first feature patterns arranged in a first direction and extending in a second direction cross the first direction, a second feature patterns arranged in the first and second directions in which the first features are between the second features, and third feature patterns between the first feature patterns and between the second feature patterns. Each of the first and second feature patterns includes a first pattern and second patterns sandwiching the first pattern there between. The third feature patterns, the first pattern and the second patterns have transmittances greater than 97%, and the second patterns can allow the light beam passed through the second patterns to have a phase difference of about 177° to about 183° with the light beam passed through the first pattern and the third feature pattern.

### CROSS-REFERENCE TO RELATED APPLICATION

This application claims the priority benefit of Taiwan application serial no. 114101268, filed on Jan. 13, 2025. The entirety of the above-mentioned patent application is hereby incorporated by reference herein and made a part of this specification.

### BACKGROUND

### Technical Field

The present invention relates to a mask for a semiconductor manufacturing process, and particularly to a phase-shifting photomask.

### Description of Related Art

As the sizes of electronic devices continue to shrink and the user's requirements for the performance of the electronic devices continue to increase, a person having ordinary skill in the art strives for allowing the electronic devices including more components while maintaining the existing horizontal area, or maintaining the number of the existing components while having a minimized horizontal area. However, either of the situations needs to reduce the feature sizes of the devices or the line widths of the interconnections.

In the current processes, an extreme ultraviolet (EUV) with a small exposure wavelength is usually used as the light source for the exposure machine, as such the interconnections with fine line widths or the devices with compact feature sizes can be realized by narrowing the wavelength of the exposure light source. However, the lithography process that uses the EUV as the light source is expensive and energy-consuming, and in the case where the sizes of the electronic devices continue to shrink, the lithography process using the EUV as the light source will still be unable to satisfy the desired size at that time. Accordingly, there is a continuous need for a person having ordinary skill in the art to find the ways other than narrowing the wavelength of the exposure light source.

### SUMMARY

The present invention provides a phase-shifting photomask in which the first feature patterns, the second feature patterns, and the third feature patterns are designed to have a light transmittance greater than about 97%, and the second patterns in the first feature patterns and the second feature patterns are configured to allow a light beam passed therethrough to have a phase difference of about 177° to about 183° with a light beam passed through the first pattern and the third feature patterns, so that the resolution of the phase-shifting photomask can be increased by allowing the exposure light source to have uniform light intensity at the target region after passing through the phase-shifting photomask, and therefore feature patterns are formed to have uniform and compact feature sizes.

An embodiment of the present invention provides a phase-shifting photomask including plurality of first feature patterns, a plurality of second feature patterns, and a plurality of third feature patterns. The first feature patterns are arranged in a first direction and extend in a second direction crossing the first direction. The second feature patterns are arranged in the first direction and the second direction, and the first feature patterns are between the second feature patterns. The third feature patterns are located between the first feature patterns and between the second feature patterns. Each of the first feature patterns and the second feature patterns includes a first pattern and second patterns sandwiching the first pattern therebetween. The third feature patterns, the first pattern, and the second patterns have a light transmittance greater than about 97%, and the second patterns are configured to allow a light beam passed therethrough to have a phase difference of about 177° to about 183° with a light beam passed through the first pattern and the third feature patterns.

In some embodiments, a width of the first pattern is about equal to widths of the second patterns.

In some embodiments, each of the first pattern and the third feature patterns includes a material capable of allowing a phase of the light beam shifting about 0° as the light beam passed therethrough.

In some embodiments, the material of each third feature pattern is the same as the material of the first pattern.

In some embodiments, the second patterns include materials capable of allowing a phase of the light beam shifting about 180° as the light beam passed therethrough.

In some embodiments, materials of the second patterns are the same as the material of the first pattern, and the second patterns have thicknesses capable of allowing a phase of the light beam shifting about 180° as the light beam passed therethrough.

In some embodiments, each second pattern includes a first portion and a second portion on the first portion, a material of the first portion is the same as the material of the first pattern, and the second portion has a thickness capable of allowing a phase of the light beam shifting about 180° as the light beam passed therethrough.

In some embodiments, the light beam passing through the second patterns and the light beam passing through the first pattern and the third feature patterns include an off-axis illumination.

In some embodiments, the off-axis illumination includes a C-quad illumination mode.

In some embodiments, the first direction is orthogonal to the second direction.

In some embodiments, each of the first feature patterns and the second feature patterns further includes a third pattern having a light transmittance greater than about 97%, the second pattern is sandwiched between the first pattern and the third pattern, and the third pattern includes a material capable of allowing a phase of a light beam shifting about 0° as the light beam passed therethrough.

In some embodiments, the material of the third pattern is the same as a material of the first pattern.

In some embodiments, a width of the third pattern is about equal to widths of the second patterns.

In some embodiments, both ends of the second feature patterns in the first direction are in contact with the first feature patterns.

Based on the above, in the above phase-shifting photomask, the first feature patterns, the second feature patterns, and the third feature patterns are configured to have a light transmittance greater than about 97%, and the second patterns in the first feature patterns and the second feature patterns are configured to allow a light beam passed therethrough to have a phase difference of about 177° to about 183° with a light beam passed through the first pattern and the third feature patterns, so that the resolution of the phase-shifting photomask can be enhanced by allowing the exposure light source to have uniform light intensity at the target region after passing through the phase-shifting photomask, and thereby forming feature patterns with uniform and compact feature sizes.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic top view illustrating a phase-shifting photomask according to an embodiment of the present invention.

FIG. 2 is a schematic enlarged view of region R1 in FIG. 1.

FIG. 3A is a diagram showing the relationship between the position and the light intensity measured along line B1-B1′ in FIG. 2.

FIG. 3B is a diagram showing the relationship between the position and the light intensity measured along line B2-B2′ in FIG. 2.

FIG. 3C is a diagram showing the relationship between the position and the light intensity measured along line B3-B3′ in FIG. 2.

FIG. 4A is a schematic cross-sectional view taken along line A-A′ in FIG. 2 according to an embodiment of the present invention.

FIG. 4B is a schematic cross-sectional view taken along line A-A′ in FIG. 2 according to another embodiment of the present invention.

### DESCRIPTION OF THE EMBODIMENTS

Reference is made to the figures of this embodiment to more comprehensively elucidate the present invention. However, the present invention may be embodied in various different forms and should not be limited to the embodiments described herein. The thicknesses of layers and regions in the figures are exaggerated for clarity. The same or similar reference numbers indicate the same or similar components, which will not be redundantly described in the following paragraphs.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

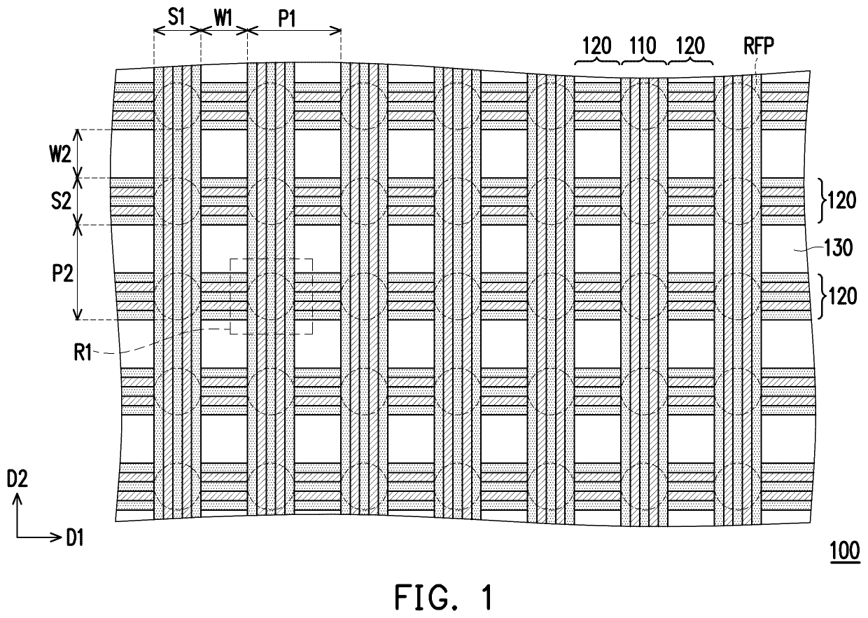

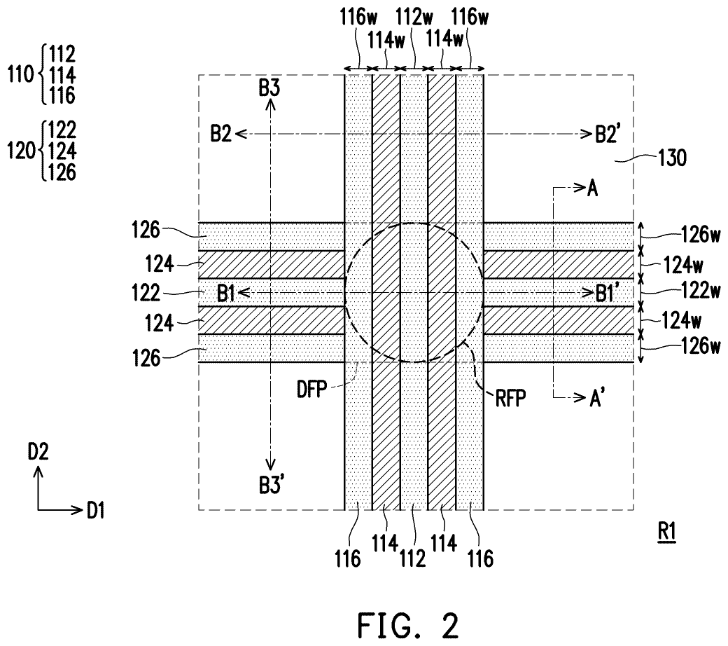

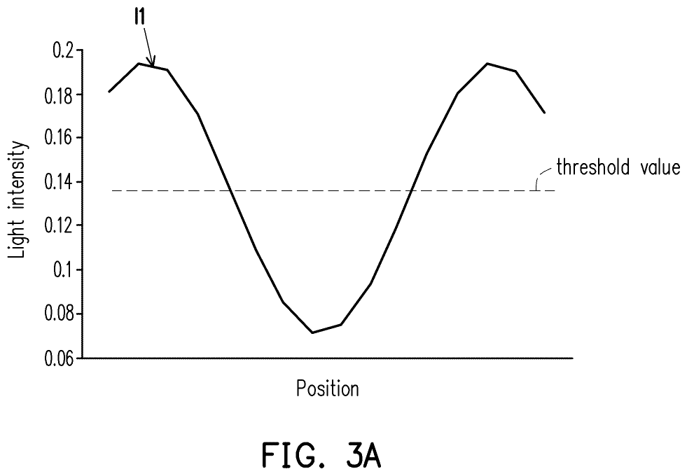

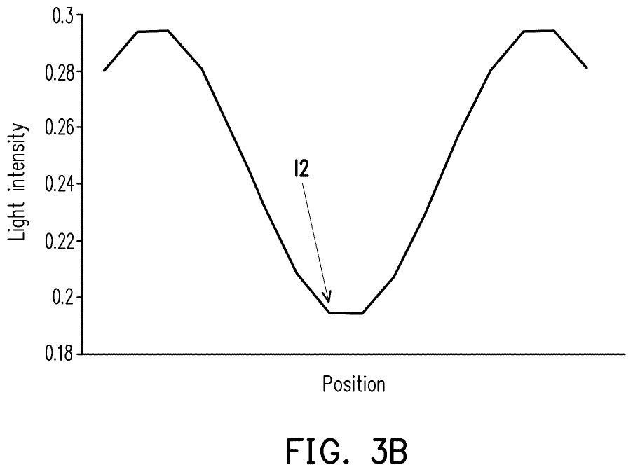

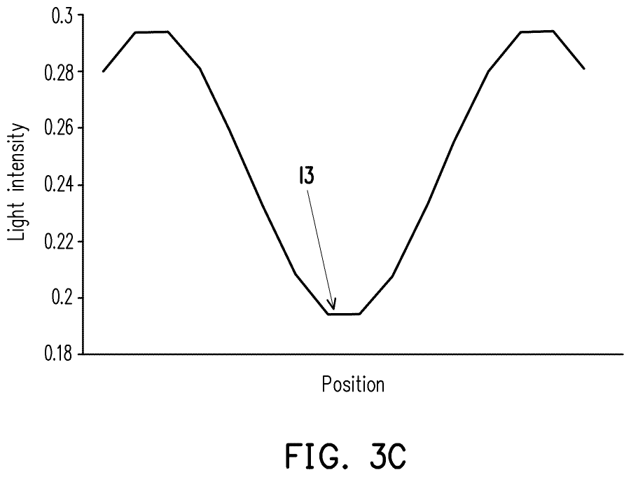

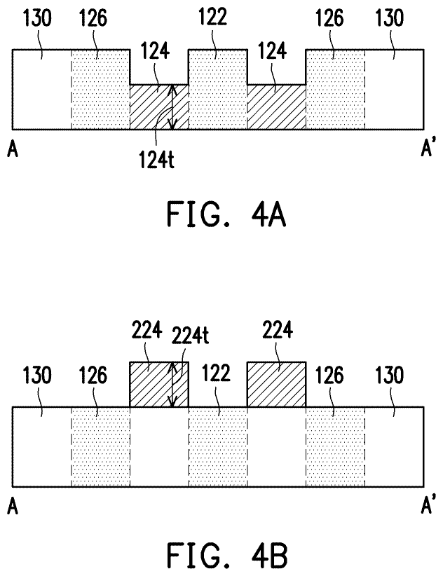

FIG. 1 is a schematic top view illustrating a phase-shifting photomask according to an embodiment of the present invention. FIG. 2 is a schematic enlarged view of region R1 in FIG. 1. FIG. 3A is a diagram showing the relationship between the position and the light intensity measured along line B1-B1′ in FIG. 2. FIG. 3B is a diagram showing the relationship between the position and the light intensity measured along line B2-B2′ in FIG. 2. FIG. 3C is a diagram showing the relationship between the position and the light intensity measured along line B3-B3′ in FIG. 2. FIG. 4A is a schematic cross-sectional view taken along line A-A′ in FIG. 2 according to an embodiment of the present invention. FIG. 4B is a schematic cross-sectional view taken along line A-A′ in FIG. 2 according to another embodiment of the present invention.

Referring to FIG. 1 and FIG. 2, the phase-shifting photomask 100 includes a plurality of first feature patterns 110, a plurality of second feature patterns 120, and a plurality of third feature patterns 130. The first feature patterns 110 are arranged in a first direction D1 and extend in a second direction D2 crossing the first direction D1. The second feature patterns 120 are arranged in the first direction D1 and the second direction D2, and the first feature patterns 110 are located between the second feature patterns 120. The third feature patterns 130 are located between the first feature patterns 110 and between the second feature patterns 120. Each of the first feature patterns 110 and the second feature patterns 120 includes a first pattern 112, 122 and second patterns 114, 124 sandwiching the first pattern 112, 122 therebetween. In some embodiments, the first direction D1 is orthogonal to the second direction D2. In some embodiments, as shown in FIG. 1, the second feature patterns 120 are in contact with the first feature patterns 110 at both ends in the first direction D1.

In this embodiment, the third feature patterns 130, the first pattern 112, 122, and the second patterns 114, 124 have a light transmittance greater than about 97%, and the second patterns 114, 124 are configured to allow a light beam passed therethrough to have a phase difference of about 177° to about 183° with a light beam passed through the first pattern 112, 122 and the third feature patterns 130. As a result, the exposure light source can have uniform light intensity at the target region after passing through the phase-shifting photomask 100, so that the resolution of the phase-shifting photomask 100 can be enhanced, and therefore feature patterns can be formed to have uniform and compact feature sizes. In some embodiments, the third feature patterns 130, the first pattern 112, 122, and the second patterns 114, 124 may each include a material with a light transmittance of about 98%, 99%, or 100%.

For example, in the case where a negative photoresist is used, the target region may be a region other than the regions where the feature patterns are to be formed (e.g., the peripheral region outside the feature patterns RFP shown in FIG. 1 and FIG. 2). According to the results shown in FIG. 3A to FIG. 3C, the light intensity at the positions where the feature patterns RFP are to be formed is all below the threshold value and will be removed in the subsequent development process, while the peripheral region of the feature patterns RFP (e.g., the positions of light intensities I1, I2, I3 shown in FIG. 3A to FIG. 3C) has uniform light intensity above the threshold value, thus can be retained in the subsequent development process. In this embodiment, as shown in FIG. 3A to FIG. 3C, the light intensities I1, I2, I3 are approximately the same. In some embodiments, as shown in FIG. 3A, the light intensity I1 may be about 0.193, while the light intensity at the center of the position where the feature patterns RFP are to be formed may be about 0.08. As such, it can be calculated to prove that the phase-shifting photomask 100 of the present invention has an improved contrast value (e.g., increased from 0 to 0.41) and thus has good resolution. It is worth noting that the above values are used as examples to more concretely demonstrate the effects produced by the present invention, and are not intended to limit the present invention.

In this embodiment, the first pattern 112 and the first pattern 122 are sandwiched between the second patterns 114 and the second patterns 124, respectively, wherein the first pattern 112, 122 and the second patterns 114, 124 have a light transmittance greater than about 97%, and the second patterns 114, 124 is designed to allow a light beam passed therethrough to have a phase difference of about 177° to about 183° with a light beam passed through the first pattern 112, 122 (e.g., the light beam passed through the first pattern 112, 122 has a phase shift angle of about 0° , while the light beam passed through the second patterns 114, 124 has a phase shift angle of about 180° ), so as to prevent the zero-order diffracted light from appearing in the desired region (i.e., regions where the feature patterns RFP are formed) through the phase cancellation, and thus it is unable to perform an interferometric optical imaging in the desired region. As such, the light intensities at the positions where the feature patterns RFP are to be formed are all below the threshold value. In this embodiment, the width 112w, 122w of the first pattern 112, 122 is designed to be about equal to the widths 114w, 124w of the second patterns 114, 124, so that the zero-order diffracted light is not occurred in the desired region (i.e., regions where the feature patterns RFP are formed) through the above phase cancellation and thus the above interference optical imaging is not performed accordingly.

Referring to FIG. 2 and FIG. 3A to FIG. 3C, the portion where the first feature patterns 110 and the second feature patterns 120 that are intersected with each other is square patterns DFP (i.e., predetermined contours of the feature patterns) . However, in the case where the third feature patterns 130 are designed to have a light transmittance greater than about 97% and the light beam passed therethrough is designed to have a phase shift angle of 0° , for example, an additional zero-order diffracted light is irradiated from the third feature patterns 130 to the four corner regions of the square pattern DFP adjacent to the third feature patterns 130 (as shown in FIG. 2). As such, the zero-order diffracted light and the first-order diffracted light can perform the interferometric optical imaging, so that the feature patterns RFP formed after the exposure and development processes have circular contours.

In this embodiment, the light beam passing through the second patterns 114, 124 and the light beam passing through the first pattern 112, 122 and the third feature patterns 130 may include an off-axis illumination. In some embodiments, the off-axis illumination includes a C-quad illumination mode.

In some embodiments, the first pattern 112, 122 and the third feature patterns 130 may have a light transmittance greater than about 97% and may each include a material that allows a phase of the light beam shifting about 0° as the light beam passed therethrough. For example, the first pattern 112, 122 and the third feature patterns 130 may include materials having the light transmittance of 100% and the phase of the light beam passed therethrough being not shifted, such as a transparent material (e.g., quartz). In some embodiments, the materials of the third feature patterns 130 may be the same as the material of the first pattern 112, 122.

In some embodiments, the second patterns 114, 124 may include materials that may be capable of allowing a phase of the light beam shifting about 180° as the light beam passed therethrough. For example, the phase angle of the light beam passed through the second patterns 114, 124 may be estimated using the following Formula 1.

$$P = 2 π ( n - 1 ) T / λ \qquad [ Formula 1 ]$$

In Formula 1, P is the phase angle, n is the refractive index of the second patterns 114, 124, T is the thicknesses of the second patterns 114, 124, and λ is the wavelength of the light beam. In some embodiments, the wavelength of the light beam may be 193 nm (e.g., an exposure light source using ArF). According to the above Formula 1, in some embodiments, the materials of the second patterns 124 may be the same as the material of the first pattern 122 (e.g., both may be made of quartz) and may be designed to have a thickness 124t (as shown in FIG. 4A) that allows the phase of the light beam shifting about 180° as the light beam passed therethrough. The thickness 124t may be less than the thickness of the first pattern 112 to have a groove shape as shown in FIG. 4A. In other embodiments, as shown in FIG. 4B, the second patterns 224 may each include a first portion and a second portion on the first portion, where the material of the first portion may be the same as the material of the first pattern 122, while the second portion may have a thickness that allows the phase of the light beam shifting about 180° as the light beam passed through the second patterns 224. In this embodiment, the second portions of the second patterns 224 may include materials such as hybrid organic siloxane polymer (HOSP), methyl silsesquioxane (MSQ), or hydrogen silsesquioxane (HSQ), which may be formed on the first portion of the second pattern 224 by a spin coating manner, for example.

In some embodiments, the phase-shifting photomask 100 may be used in a process for forming a contact hole array. In this embodiment, as shown in FIG. 1, the feature patterns RFP may have the same size in the first direction D1 and the second direction D2. For example, the size S1 of the feature patterns RFP in the first direction D1 may be about 36 nm, and the sizes S2 in the second direction D2 may be about 36 nm. The feature patterns RFP are spaced apart by the same distance in the first direction D1 and the second direction D2. For example, the distance W1 between the adjacent feature patterns RFP in the first direction D1 may be about 36 nm, and the distance W2 between the adjacent feature patterns RFP in the second direction D2 may be about 36 nm. The feature patterns RFP may have the same pitch in the first direction D1 and the second direction D2. For example, the pitch P1 of the feature patterns RFP in the first direction D1 may be about 72 nm, and the pitch P2 of the feature patterns RFP in the second direction D2 may be about 72 nm.

In some embodiments, as shown in FIG. 2, each of the first feature pattern 110 and the second feature pattern 120 may further include a third pattern 116, 126 having a light transmittance greater than about 97%, wherein the second pattern 114, 124 is sandwiched between the first pattern 112, 122 and the third pattern 116, 126, and the third pattern 116, 126 includes a material capable of allowing the phase of light beam shifting about 0° as the light beam passed therethrough. For example, the third pattern 116, 126 may include a material having the light transmittance of 100% and the phase of the light beam passed therethrough being not shifted, such as a transparent material (e.g., quartz). In some embodiments, the material of the third pattern 116, 126 may be the same as the material of the first pattern 112, 122. In some embodiments, the width 116w, 126w of the third pattern 116, 126 may be about equal to the width 114w, 124w of the second pattern 114, 124.

In summary, in the above-mentioned phase-shifting photomask, the first feature pattern the second feature patterns, and the third feature patterns are configured to have a light transmittance greater than about 97%, and the second patterns in the first feature patterns and the second feature patterns are configured to allow a light beam passed therethrough to have a phase difference of about 177° to about 183° with a light beam passed through the first pattern and the third feature patterns, so that the resolution of the phase-shifting photomask can be enhanced by allowing the exposure light source to have uniform light intensity at the target region after passing through the phase-shifting photomask, and thereby forming feature patterns with uniform and compact feature sizes.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A phase-shifting photomask, comprising:
a plurality of first feature patterns arranged in a first direction and extending in a second direction crossing the first direction;
a plurality of second feature patterns arranged in the first direction and the second direction, and the first feature patterns are between the second feature patterns; and
a plurality of third feature patterns between the first feature patterns and between the second feature patterns,
wherein each of the first feature patterns and the second feature patterns comprises a first pattern and second patterns sandwiching the first pattern therebetween,
wherein the third feature patterns, the first pattern, and the second patterns have a light transmittance greater than about 97%, and the second patterns are configured to allow a light beam passed therethrough to have a phase difference of about 177° to about 183° with a light beam passed through the first pattern and the third feature patterns.

2. The phase-shifting photomask according to claim 1, wherein a width of the first pattern is about equal to widths of the second patterns.

3. The phase-shifting photomask according to claim 1, wherein each of the first pattern and the third feature patterns comprises a material capable of allowing a phase of the light beam shifting about 0° as the light beam passed therethrough.

4. The phase-shifting photomask according to claim 3, wherein the material of each third feature pattern is the same as the material of the first pattern.

5. The phase-shifting photomask according to claim 3, wherein the second patterns comprise materials capable of allowing a phase of the light beam shifting about 180° as the light beam passed therethrough.

6. The phase-shifting photomask according to claim 3, wherein materials of the second patterns are the same as the material of the first pattern, and the second patterns have thicknesses capable of allowing a phase of the light beam shifting about 180° as the light beam passed therethrough.

7. The phase-shifting photomask according to claim 3, wherein each second pattern comprises a first portion and a second portion on the first portion, a material of the first portion is the same as the material of the first pattern, and the second portion has a thickness capable of allowing a phase of the light beam shifting about 180° as the light beam passed therethrough.

8. The phase-shifting photomask according to claim 1, wherein the light beam passing through the second patterns and the light beam passing through the first pattern and the third feature patterns comprise an off-axis illumination.

9. The phase-shifting photomask according to claim 8, wherein the off-axis illumination comprises a C-quad illumination mode.

10. The phase-shifting photomask according to claim 1, wherein the first direction is orthogonal to the second direction.

11. The phase-shifting photomask according to claim 1, wherein each of the first feature patterns and the second feature patterns further comprises a third pattern having a light transmittance greater than about 97%, the second pattern is sandwiched between the first pattern and the third pattern, and the third pattern comprises a material capable of allowing a phase of a light beam shifting about 0° as the light beam passed therethrough.

12. The phase-shifting photomask according to claim 11, wherein the material of the third pattern is the same as a material of the first pattern.

13. The phase-shifting photomask according to claim 12, wherein a width of the third pattern is about equal to widths of the second patterns.

14. The phase-shifting photomask according to claim 1, wherein both ends of the second feature patterns in the first direction are in contact with the first feature patterns.
